(19) United States
(12) Patent Application Publication
(10) Pub. No.: US 2022/0065550 A1
(43) Pub. Date: Mar. 3, 2022

(54) HEAT CONDUCTION MEMBER

(71) Applicants: Nidec Chaun-Choung Technology Corporation, New Taipei City (TW); Nidec Corporation, Kyoto (JP)

(72) Inventors: Masaaki HANANO, Kyoto (JP); Junichi ISHIDA, Kyoto (JP); Toshihiko KOSEKI, Kyoto (JP)

(21) Appl. No.: 17/458,625

(22) Filed: Aug. 27, 2021

(30) Foreign Application Priority Data
Aug. 31, 2020 (JP) 2020-146411

(51) Int. Cl. F28D 15/04

(52) U.S. Cl. CPC F28D 15/04

(57) ABSTRACT

A heat conductor includes a housing including a space therein and a working medium in the space. The housing includes an upper plate on an upper side of the housing in a thickness direction and covering an upper side of the space, a lower plate on a lower side of the space and opposing the upper plate in the thickness direction, and pillars located between the upper plate and the lower plate. The housing further includes bent portions in which both the upper plate and the lower plate are bent in a same direction in the thickness direction. The pillars are located only outside at least one section between two of the bent portions.

### CROSS-REFERENCE TO RELATED APPLICATIONS

The present application claims priority under 35 U.S.C. § 119 to Japanese Patent Application No. 2020-146411, filed on Aug. 31, 2020, the entire contents of which are incorporated herein by reference.

### FIELD OF THE INVENTION

The present disclosure relates to a heat conductor.

### BACKGROUND

Conventionally, a vapor chamber is used as a heat conductor for dissipating heat of a heat generator. Additionally, there has been proposed a thinned vapor chamber with reduced thickness. The space in the vapor chamber is provided with a capillary member formed at the bottom and an evaporation space between the capillary member and a lid. The vapor chamber has multiple supports that are in contact with the capillary member and the lid.

When the vapor chamber is bent according to an installation place or the like, the thickness of the vapor chamber is reduced, and further, if there is a support in the vapor chamber, there has been a problem that a space for returning the working fluid cannot be secured inside. As a result, it has not been easy to bend the vapor chamber into a desired three-dimensional shape.

### SUMMARY

An example embodiment of a heat conductor of the present disclosure includes a housing including a space therein and a working medium in the space. The housing includes an upper plate located on an upper side of the housing in a thickness direction and covering an upper side of the space, a lower plate located on a lower side of the space and opposing the upper plate in the thickness direction, and pillars located between the upper plate and the lower plate. The housing further includes bent portions in which both the upper plate and the lower plate are bent in a same direction in the thickness direction. The pillars are located only outside at least one section between the two bent portions.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a longitudinal section of a heat conductor of an example embodiment of the present disclosure.

FIG. 2 is a longitudinal section illustrating a portion of the manufacturing process of the heat conductor.

FIG. 3 is a longitudinal section illustrating a portion of the manufacturing process of the heat conductor.

FIG. 4 is a partial longitudinal section illustrating a bent portion of the heat conductor.

FIG. 5 is a transverse section of the heat conductor.

FIG. 6 is a partial longitudinal section illustrating a positional relationship between a bent portion and a pillar of the heat conductor.

FIG. 7 is a partial longitudinal section of a heat conductor of a first modification of an example embodiment of the present disclosure.

FIG. 8 is a partial plan view of the heat conductor of the first modification.

### DETAILED DESCRIPTION

Example embodiments of the present disclosure will be described below with reference to the drawings. Note that the scope of the present disclosure is not limited to the example embodiments described below, but includes any modification thereof within the scope of the technical idea of the present disclosure.

In the drawings, an XYZ coordinate system is appropriately illustrated as a three-dimensional orthogonal coordinate system. The X direction, the Y direction, and the Z direction are orthogonal to one another. In the present specification, a normal direction of one surface of a heat conductor 1 facing a heat generator H to be described later is referred to as a “vertical direction” (Z direction), and a direction orthogonal to the vertical direction is referred to as a “horizontal direction” (X direction and Y direction). In a heated portion 11 of the heat conductor 1 facing the heat generator H, the vertical direction (Z direction) coincides with a “thickness direction” of a housing 2. A side on which the heat conductor 1 is located with respect to the heat generator H is referred to as an “upper side”, and a side on which the heat generator H is located with respect to the heat conductor 1 is referred to as a “lower side”. The shape and positional relationship among parts of the heat conductor will be described on the basis of these directions. Note that the definitions of these directions do not limit the orientation and positional relationship of the heat conductor at the time of use.

Additionally, in the present specification, a cross section parallel to the vertical direction is referred to as a “longitudinal section”, and a cross section parallel to the horizontal direction orthogonal to the vertical direction is referred to as a “transverse section”. Additionally, the expressions “parallel” and “orthogonal” do not refer only to mathematically strictly parallel and orthogonal, but also include parallel and orthogonal to the degree to which the effect of the present disclosure is exhibited, for example.

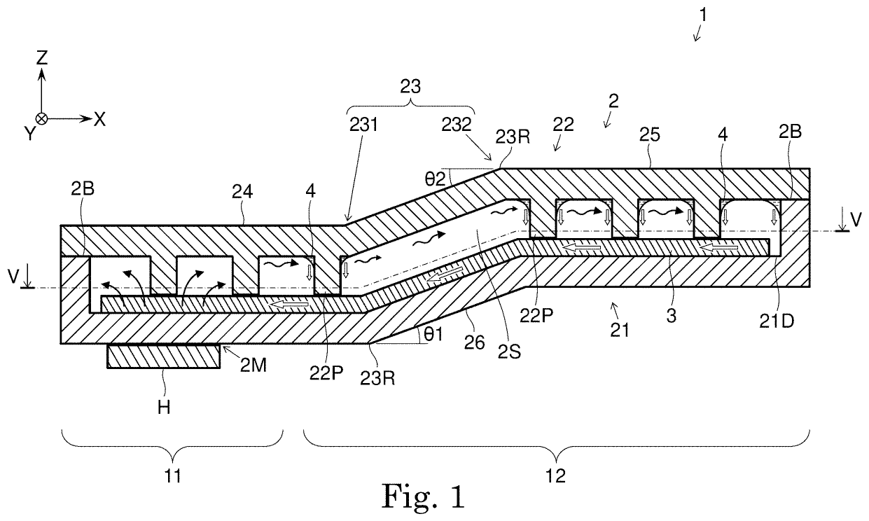

FIG. 1 is a longitudinal section of the heat conductor of an example embodiment of the present disclosure. In the present example embodiment, the heat conductor 1 is a so-called vapor chamber that transports heat of the heat generator H. The heat generator H is an electronic component that generates heat or a substrate on which the electronic component is mounted, for example. The heat generator H is cooled by having its heat transported by the heat conductor 1. The heat conductor 1 is mounted on an electronic device having the heat generator H, such as a smartphone or a laptop. Note that the number of heat generators H is not limited to one, and may be plural.

The heat conductor 1 has the heated portion 11 and a heat dissipating portion 12. The heated portion 11 is located adjacent to the heat generator H, for example, and is heated by heat generated by the heat generator H. The heat dissipating portion 12 dissipates the heat received from the heat generator H in the heated portion 11 to the outside. Furthermore, in the present example embodiment, the heat conductor 1 has a housing 2, a wick structure 3, and a working medium 4.

The housing 2 is formed of metal such as copper, for example, and is a box that has a space 2S therein and is rectangular when viewed in the vertical direction. A part of the housing 2 is included in the heated portion 11. Another part of the housing 2 is included in the heat dissipating portion 12. The space 2S is a sealed space, and is maintained in a depressurized state where the atmospheric pressure is lower than the barometric pressure, for example. Since the space 2S is in the depressurized state, the working medium 4 accommodated in the space 2S is easily evaporated.

The wick structure 3 is disposed in the space 2S of the housing 2. The wick structure 3 extends continuously from a region included in the heated portion 11 to a region included in the heat dissipating portion 12 in the space 2S. The wick structure 3 is formed of a metal net-like member (metal mesh), for example, and transports the working medium 4 by capillary action.

Note that the wick structure 3 is not limited to a metal net-like member (metal mesh), as long as it has a structure capable of transporting the working medium 4 in the space 2S. The wick structure 3 may be, for example, a sintered wick formed of a porous copper sintered body, a groove wick having a groove structure, or the like.

The working medium 4 is accommodated in the space 2S of the housing 2. The working medium 4 is water, for example, but may be another liquid such as alcohol. The working medium 4 transports heat by moving in the space 2S including the inside of the wick structure 3.

As described above, the heat conductor 1 of the present example embodiment includes the housing 2 having the space 2S therein and the working medium 4 disposed in the space 2S.

The housing 2 includes a lower plate 21 and an upper plate 22. Furthermore, the housing 2 has multiple pillars 22P.

The lower plate 21 is located in a lower part of the housing 2. The lower plate 21 faces the upper plate 22 in the thickness direction of the housing 2 and is located below the space 2S. The lower plate 21 is a metal plate, and is a copper plate, for example. The lower plate 21 may be formed by applying copper plating to a surface of a metal plate other than copper, such as stainless steel.

The lower plate 21 has a recess 21D. The recess 21D is formed in a recessed shape in which the inside is recessed downward from an outer edge portion of the lower plate 21 in the horizontal direction. The wick structure 3 is disposed in the recess 21D. That is, the lower plate 21 supports the wick structure 3 from below.

The upper plate 22 is located in an upper part of the housing 2. The upper plate 22 is made of the same metal plate as the lower plate 21. That is, the upper plate 22 is a copper plate, for example. The upper plate 22 may be formed by applying copper plating to a surface of a metal plate other than copper, such as stainless steel. Note that the upper plate 22 and the lower plate 21 may be made of different metals.

The upper plate 22 is located above the lower plate 21 and faces the lower plate 21 in the thickness direction of the housing 2. The upper plate 22 is located on the upper side in the thickness direction of the housing 2 and covers the upper side of the space 2S. That is, the upper plate 22 covers the upper side of the wick structure 3 in the space 2S.

The upper plate 22 is formed integrally with the multiple pillars 22P. The multiple pillars 22P extend downward from a lower surface of the upper plate 22 and come into contact with the wick structure 3. That is, the multiple pillars 22P are located between the upper plate 22 and the lower plate 21. The pillars 22P may be formed of the same member as the upper plate 22, or may be formed of a member different from upper plate 22. The pillar 22P is a support for holding the wick structure 3 at a lower portion in the space 2S, and can also make the thickness of the housing 2 constant.

Note that the pillars may be formed in the lower plate 21. In this case, the pillar extends upward from a bottom surface in the recess 21D of the lower plate 21. That is, the wick structure 3 is disposed on the upper side in the space 2S.

The housing 2 further has a joint portion 2B. The joint portion 2B is a joint structure in which the lower plate 21 and the upper plate 22 are joined to each other at outer edges thereof. The joint portion 2B is located around the space 2S when viewed in the vertical direction, and joins the lower plate 21 and the upper plate 22. The method for joining the lower plate 21 and the upper plate 22 is not particularly limited. Various joining methods such as a method of joining by applying heat and pressure, a method of joining using a brazing material, and the like may be used for the joint portion 2B.

The joint portion 2B may include a sealed portion. The sealed portion is, for example, a part where an injection port for injecting the working medium 4 into the housing 2 is sealed by welding in the manufacturing process of the heat conductor 1.

The housing 2 has a heat generator mounting portion 2M on a lower surface thereof. The heat generator mounting portion 2M is located in the heated portion 11. One heat generator mounting portion 2M is provided, for example, so as to match the number of the heat generator H. The heat generator mounting portion 2M overlaps the wick structure 3 when viewed in the vertical direction.

In FIG. 1, the flow of steam generated by vaporization of the working medium 4 is indicated by a black arrow in the housing 2. Additionally, in FIG. 1, the flow of the liquid working medium 4 is indicated by a hollow arrow in the housing 2.

The heat of the heat generator H is transmitted to the wick structure 3 through the lower plate 21 in the heated portion 11. When the temperature of the wick structure 3 rises, the liquid working medium 4 contained in the wick structure 3 is vaporized, and steam is generated. The steam of the working medium 4 moves toward the heat dissipating portion 12 in the space 2S. The steam of the working medium 4 is cooled and liquefied by heat dissipation in the heat dissipating portion 12.

The liquefied working medium 4 flows along an inner surface of the housing 2 and moves in the wick structure 3 by capillary action, thereby flowing toward the heated portion 11. As the working medium 4 moves while changing its state in this manner, heat is continuously transported from the heated portion side to the heat dissipating portion 12 side in the heat conductor 1. As a result, the heat generator H in contact with the heated portion 11 is cooled by the heat conductor 1.

The housing 2 further has a bent portion 23. In the present example embodiment, the bent portion 23 includes a first bent portion 231 and a second bent portion 232. The first bent portion 231 and the second bent portion 232 are juxtaposed in parallel from an end portion of the heat conductor 1 on the heated portion 11 side toward an end portion thereof on the heat dissipating portion 12 side.

In the present example embodiment, the first bent portion 231 and the second bent portion 232 extend along the horizontal direction (Y direction in FIG. 1) of the housing 2. In other words, the first bent portion 231 and the second bent portion 232 extend in a direction (Y direction in FIGS. 1 and 5) parallel to a side of the housing 2 having a rectangular shape when viewed in the vertical direction, the side facing a direction in which the heated portion 11 and the heat dissipating portion 12 are arranged. That is, the Y direction in FIG. 1 is an extending direction of the first bent portion 231 and the second bent portion 232, and is a direction in which ridge lines 23R of the first bent portion 231 and the second bent portion 232 extend (see FIG. 5). In the first bent portion 231 and the second bent portion 232, both the upper plate 22 and the lower plate 21 are bent in the same direction in the thickness direction of the housing 2.

Note that the bent portion 23 is not limited to the form in which it is bent linearly along the Y direction as illustrated in FIG. 1. The bent portion 23 may be curved in an arc shape when viewed in the Y direction.

The housing 2 further has a first horizontal portion 24, a second horizontal portion 25, and an inclined portion 26. The first horizontal portion 24, the second horizontal portion 25, and the inclined portion 26 are separated by the first bent portion 231 and the second bent portion 232. In the heat conductor 1, the first horizontal portion 24, the inclined portion 26, and the second horizontal portion 25 are continuous in this order from the end portion on the heated portion 11 side toward the end portion on the heat dissipating portion 12 side. The heated portion 11 is disposed in the first horizontal portion 24. Each of the first horizontal portion 24, the second horizontal portion 25, and the inclined portion 26 includes a part of the lower plate 21 and a part of the upper plate 22.

The first horizontal portion 24 and the second horizontal portion 25 extend in the horizontal direction (X direction and Y direction in FIG. 1). That is, in each of the first horizontal portion 24 and the second horizontal portion 25, both the lower plate 21 and the upper plate 22 extend along the horizontal direction. In the present example embodiment, the first horizontal portion 24 and the second horizontal portion 25 extend parallel to each other. The first horizontal portion 24 and the second horizontal portion 25 may be inclined at a predetermined angle when viewed in the Y direction.

The inclined portion 26 is inclined upward in the vertical direction (Z direction in FIG. 1) at a predetermined angle θ1 with respect to the first horizontal portion 24, and is inclined downward in the vertical direction (Z direction in FIG. 1) at a predetermined angle θ2 with respect to the second horizontal portion 25. That is, in the inclined portion 26, both the lower plate 21 and the upper plate 22 are inclined upward in the vertical direction at a predetermined angle θ1 with respect to the first horizontal portion 24, and are inclined downward in the vertical direction at a predetermined angle θ2 with respect to the second horizontal portion 25. In the present example embodiment, since the first horizontal portion 24 and the second horizontal portion 25 are parallel to each other, the angle θ1 and the angle θ2 are the same angle. The angle θ1 and the angle θ2 may be different angles that can be appropriately set to arbitrary angles.

As a result, the second horizontal portion 25 is located above the first horizontal portion 24 in the vertical direction (Z direction in FIG. 1).

As illustrated in FIG. 1, the wick structure 3 is located over regions on both sides of the bent portion 23 in a direction (X direction) intersecting the extending direction (Y direction) of the ridge line 23R of the bent portion 23. In other words, the wick structure 3 is located from the region on the heated portion side of the heat conductor 1 to the region on the heat dissipating portion 12 side of the heat conductor 1. According to this configuration, the working medium 4 can be easily returned.

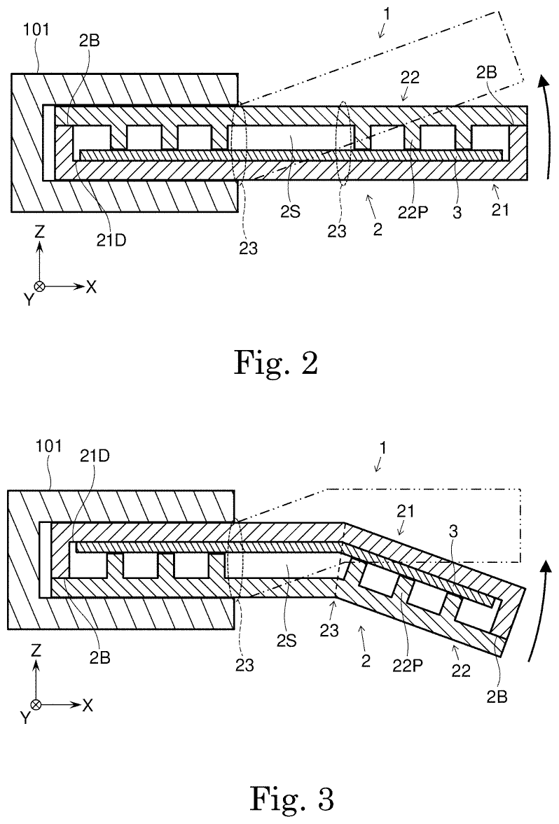

FIGS. 2 and 3 are longitudinal sections illustrating a part of the manufacturing process of the heat conductor 1. The heat conductor 1 can be manufactured by the following method. Note that the method for manufacturing the heat conductor 1 is not limited to the following method, and may be another method.

First, the lower plate 21 in which the recess 21D recessed downward is formed on the inner side in the horizontal direction, the upper plate 22 in which the multiple pillars 22P extending downward is formed on the inner side in the horizontal direction, and the wick structure 3 are produced. Next, the lower plate 21 in which the wick structure 3 is disposed in the recess 21D and the upper plate 22 are joined together at the joint portion 2B to form the housing 2 (see FIG. 2) having a flat plate shape and having no bent portion.

Next, as illustrated in FIG. 2, one end side of the housing 2 in the horizontal direction (X direction) is sandwiched and restrained by a jig 101. Next, the other end side of the housing 2 in the horizontal direction (X direction) is pushed upward in the vertical direction (Z direction) to be bent, for example, and a first bent portion 23 (e.g., first bent portion 231) is formed in the housing 2 (see FIG. 2).

Next, as illustrated in FIG. 3, the housing 2 is held differently, and the other end side of the housing 2 in the horizontal direction (X direction) is sandwiched and restrained by the jig 101. Next, one end side of the housing 2 in the horizontal direction (X direction) is pushed upward in the vertical direction (Z direction) to be bent, and a second bent portion 23 (e.g., second bent portion 232) is formed in the housing 2.

Note that while one and the other end sides of the housing 2 in the horizontal direction (X direction) are switched and are separately sandwiched by the jig 101 in FIGS. 2 and 3, both end sides of the housing 2 in the horizontal direction (X direction) may be simultaneously sandwiched and restrained by jigs to form the bent portion 23.

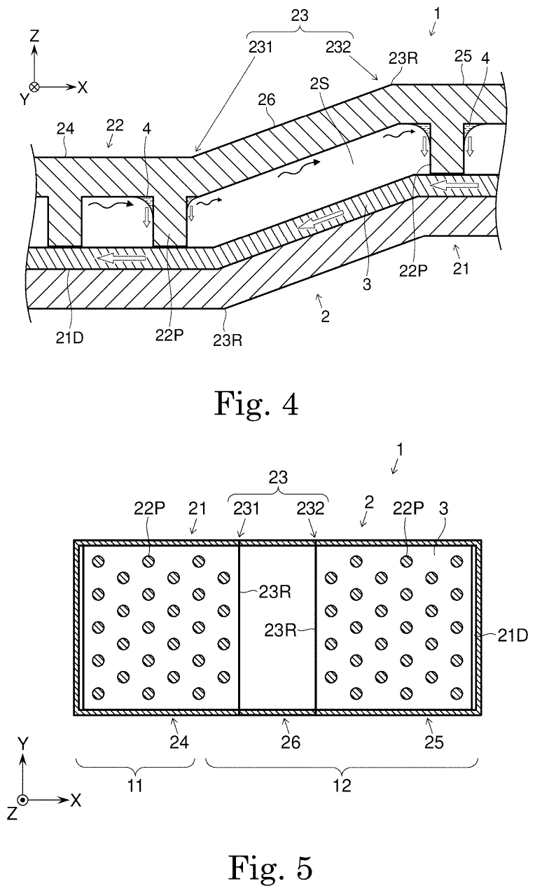

FIG. 4 is a partial longitudinal section illustrating the bent portion 23 of the heat conductor 1. FIG. 5 is a transverse section of the heat conductor 1. Note that FIG. 5 is a transverse section of the heat conductor 1 taken along line V-V in FIG. 1.

As described above, the heat conductor 1 has multiple bent portions including the first bent portion 231 and the second bent portion 232. The pillar is located only outside the section (inclined portion 26) sandwiched between the two bent portions which are the first bent portion 231 and the second bent portion 232. In other words, as illustrated in FIGS. 4 and 5, the pillar 22P is not located in the inclined portion 26 which is a section sandwiched between the first bent portion 231 and the second bent portion 232. The pillar 22P is located only in the first horizontal portion 24 and the second horizontal portion 25. Note that when the heat conductor 1 has three or more bent portions, the pillar 22P is located only outside at least one section sandwiched between the two bent portions.

Forming the first bent portion 231 and the second bent portion 232 may narrow the space 2S of the inclined portion 26 interposed therebetween. However, according to the above configuration, since the pillar 22P is not located in the inclined portion 26, there is no region occupied by the pillar 22P itself, and the space 2S can be secured in the bent portion 23. That is, it is possible to provide the heat conductor 1 capable of securing the space 2S therein even when the heat conductor 1 is bent. As a result, it becomes easy to bend the flat plate-shaped heat conductor 1 into a desired three-dimensional shape. Accordingly, even if the position of the heated portion 11 and the position of the heat dissipating portion 12 are shifted in the Z direction in FIG. 1, for example, the heat conductor 1 can effectively cool the heat generator H.

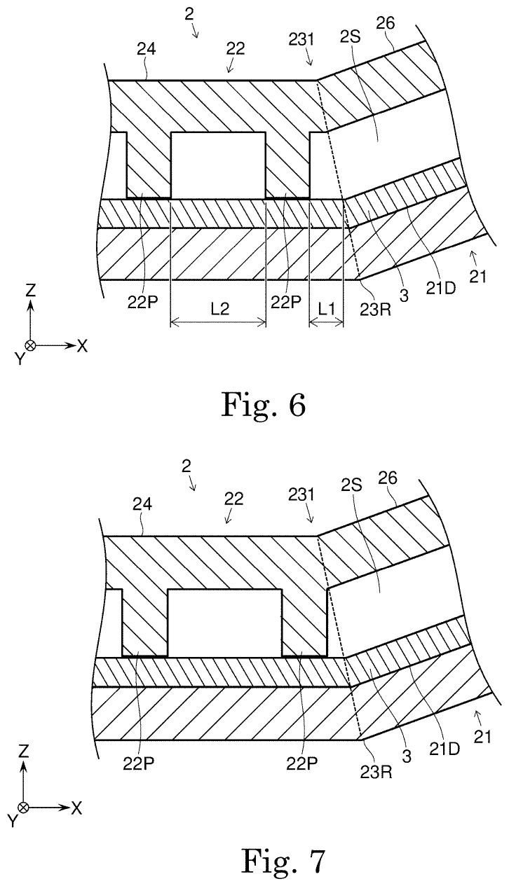

FIG. 6 is a partial longitudinal section illustrating a positional relationship between the bent portion 23 and the pillar 22P of the heat conductor 1. As illustrated in FIG. 6, for example, a distance L1 between the first bent portion 231 and the pillar 22P arranged in the direction (X direction) intersecting the extending direction of the ridge line 23R of the first bent portion 231 is shorter than a distance L2 between the pillars 22P arranged in the direction (X direction) intersecting the extending direction of the ridge line 23R of the first bent portion 231.

Note that the distance L1 between the first bent portion 231 and the pillar 22P arranged in the X direction and the distance L2 between the pillars 22P arranged in the X direction mean distances in the X direction at the same location (height) in the Z direction (vertical direction). For example, in the present example embodiment, the distances L1 and L2 mean the distances in the X direction between tip end portions (lower end portions in Z direction) of the pillars 22P arranged in the X direction at the same location in the Z direction. The distances L1 and L2 may be at root portions (upper end portions in Z direction) of the pillars 22P arranged in the X direction, at intermediate portions in the vertical direction of the pillars 22P arranged in the X direction, or the like. Additionally, the second bent portion 232 of the bent portion 23 and the pillar 22P may have a similar positional relationship.

Although the space 2S may be narrowed by forming the bent portion 23, the space 2S can be secured in the bent portion 23 by locating the pillar 22P as close to the bent portion 23 as possible as in the above configuration.

As illustrated in FIG. 5, the pillar 22P is formed in a circular cylinder when viewed in the vertical direction, for example. The multiple pillars 22P are two-dimensionally arranged at regular intervals in the horizontal direction (X direction and Y direction in FIG. 5) of the housing 2. That is, the multiple pillars 22P are juxtaposed at predetermined intervals from the end on the heated portion 11 side of the housing 2 toward the end portion on the heat dissipating portion 12 side of the housing 2.

In other words, the multiple pillars 22P are arranged at predetermined intervals over the entire region from one end portion of the outer edge of the housing 2 to the other end portion opposite to the one end portion. Specifically, the multiple pillars 22P are arranged at predetermined intervals over the entire region from a left end portion in the X direction of FIG. 5 of the outer edge of the housing 2 to a right end portion in the X direction of FIG. 5 opposite to the left end portion. Alternatively, the multiple pillars 22P are arranged at predetermined intervals over the entire region from a lower end portion in the Y direction of FIG. 5 of the outer edge of the housing 2 to an upper end portion in the Y direction of FIG. 5 opposite to the lower end portion.

Note that in the present example embodiment, the multiple pillars 22P are arranged in a triangular lattice shape. The multiple pillars 22P may be arranged in, for example, a square lattice shape, a rectangular lattice shape, or an orthorhombic lattice shape.

According to the above configuration, the pillars 22P can be arranged over the entire region of the housing 2 in the horizontal direction (X direction and Y direction in FIG. 5). This makes it possible to secure the space 2S in the entire housing 2 and improve the strength of the housing 2.

Next, a modification of the heat conductor 1 will be described. Note that since the basic configuration of the modification is the same as that of the above example embodiment described with reference to FIGS. 1 to 6, the same reference numerals or the same names may be assigned to common components, and the description thereof may be omitted.

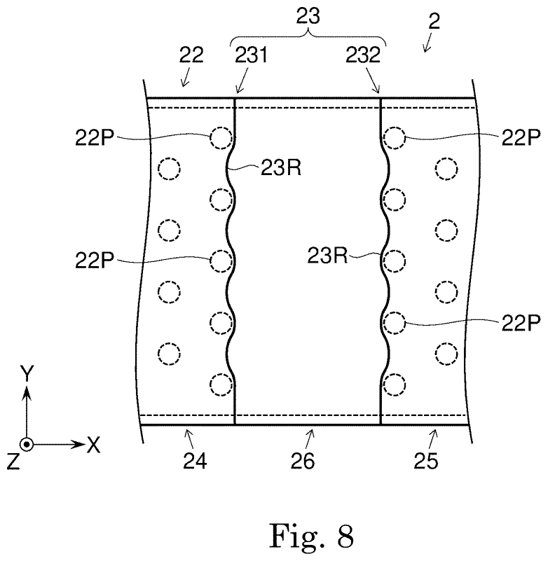

FIG. 7 is a partial longitudinal section of a heat conductor 1 of a first modification. FIG. 8 is a partial plan view of the heat conductor 1 of the first modification. As illustrated in FIG. 7, the heat conductor 1 of the first modification has a bent portion 23 (first bent portion 231) and multiple pillars 22P. The pillar 22P is located along the first bent portion 231 in the Y direction of FIG. 7.

The first bent portion 231 is adjacent to at least one pillar 22P. Furthermore, the first bent portion 231 is more preferably adjacent to multiple pillars 22P. Note that a second bent portion 232 of the bent portion 23 and the pillar 22P may have a similar positional relationship.

According to the above configuration, since the bent portion 23 is adjacent to the pillar 22P, the strength of the bent portion 23 can be improved. Additionally, a space 2S can be secured in the bent portion 23. Furthermore, when the bent portion 23 is adjacent to multiple pillars 22P, the strength of the bent portion 23 can be improved along a ridge line 23R of the bent portion 23. Additionally, it is possible to secure the space 2S along the ridge line 23R of the bent portion 23.

Additionally, the ridge line 23R of the bent portion 23 extends in a shape according to the shape and arrangement of the pillars 22P. For example, as illustrated in FIG. 8, the ridge line 23R of the bent portion 23 extends in a wave shape along the edges of the pillars 22P. As a result, the strength of the bent portion 23 can be further improved. Furthermore, when the bent portion 23 is adjacent to multiple pillars 22P, the interval between the wave-shaped mountains becomes narrow. As a result, the strength of the bent portion 23 can be improved even more.

For example, the number of the bent portions 23 is not limited to one or two, and may be three or more. Additionally, the angle formed by the regions adjacent to each other with the bent portion 23 interposed therebetween in the housing 2 is not limited to the inclination angle and the right angle described in the above example embodiments, and may be another angle. Additionally, the bent portion 23 extends in a direction (e.g., Y direction in FIG. 5) parallel to a side of the housing 2 having a rectangular shape when viewed in the vertical direction, the side facing the direction in which the heated portion 11 and the heat dissipating portion 12 are arranged. However, the bent portion 23 may extend obliquely with respect to the side facing the direction in which the heated portion 11 and the heat dissipating portion 12 are arranged.

Additionally, the number and arrangement of the multiple pillars 22P are not limited to the configuration illustrated in the figure, and may be other numbers and arrangements.

Additionally, the pillar 22P is not limited to a column having a circular cross-sectional shape when viewed in the vertical direction, and may be a column having another cross-sectional shape such as an elliptical shape or a rectangular shape.

The present disclosure can be used for heat dissipation of a board mounted on an electronic device or an electronic component, for example.

Features of the above-described preferred example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A heat conductor, comprising:
a housing including a space therein; and
a working medium in the space; wherein
the housing includes:
an upper plate located on an upper side of the housing in a thickness direction and covering an upper side of the space;
a lower plate located on a lower side of the space and opposing the upper plate in the thickness direction; and
pillars located between the upper plate and the lower plate;
the housing further includes bent portions in which both the upper plate and the lower plate are bent in a same direction in the thickness direction; and
the pillars are located only outside at least one section between two of the bent portions.

2. The heat conductor according to claim 1, wherein
a distance between the bent portions and the pillars that are arranged in a direction intersecting an extending direction of a ridge line of the bent portions is shorter than a distance between the pillars that are arranged in the direction intersecting the extending direction of the ridge line of the bent portions.

3. The heat conductor according to claim 1, wherein
each of the bent portions is each adjacent to at least one of the pillars.

4. The heat conductor according to claim 3, wherein
each of the bent portions is adjacent to at least two or more pillars.

5. The heat conductor according to claim 1, wherein
the pillars are arranged at predetermined intervals over an entire region from one end portion of an outer edge of the housing to another end portion of the outer edge opposite to the one end portion.

6. The heat conductor according to claim 1, further comprising:
a wick structure in the space; wherein
the wick structure is located over regions on two sides of the bent portions in a direction intersecting an extending direction of a ridge line of the bent portions.
